(19) United States
(12) Patent Application Publication
(10) Pub. No.: US 2014/0102519 A1
(43) Pub. Date: Apr. 17, 2014

(54) Roof Integrated Solar Panel System with Ridge Mounted Micro Inverters

(71) Applicant: Building Materials Investment Corporation, Dallas, TX (US)

(72) Inventors: Tommy F. Rodrigues, Nutley, NJ (US); Sudhir Railkar, Wayne, NJ (US); Daniel E. Boss, Murphy, TX (US); David J. Gennrich, Fitchburg, WI (US); Cory Boudreau, Lake Elmo, MN (US); Daniel Roger Nett, Sun Prairie, WI (US); Kent J. Kallsen, Jefferson, WI (US)

(73) Assignee: Building Materials Investment Corporation, Dallas, TX (US)

(21) Appl. No.: 14/050,845

(22) Filed: Oct. 10, 2013

Related U.S. Application Data
(60) Provisional application No. 61/712,283, filed on Oct. 11, 2012.

(51) Int. Cl. H01L 31/042; H01L 31/18; H01L 31/048

(52) U.S. Cl. CPC H01L 31/0428; H01L 31/0482; H01L 31/18
USPC 136/251; 29/825

(57) ABSTRACT

A solar panel system includes a plurality of solar modules that produce DC electrical energy when exposed to sunlight. Each of the solar modules includes a frame, a photovoltaic panel mounted to the frame, and an electrical coupling for outputting the DC electrical energy from the photovoltaic panel. The solar modules are mounted to the deck of a roof having a ridge and a ridge vent extending at least partially along and covering the ridge of the roof. One or more micro-inverters is located beneath the ridge vent and each is electrically connected to a bank of two or more solar modules selected from the plurality of solar modules. The micro-inverters on the roof convert the DC electrical energy produced by the photovoltaic panels to AC electrical energy, and the AC electrical energy is aggregated from the micro-inverters and delivered to a remote electrical system.

### RELATED APPLICATIONS

This application claims the benefit of U.S. Provisional Patent Application No. 61/712,283, filed on 11 Oct. 2012, and entitled “Roof Integrated Solar Panel System With Ridge Mounted Micro Inventers”, which application is incorporated by reference in its entirety herein.

### TECHNICAL FIELD

This disclosure relates generally to photovoltaic energy production and more specifically to solar panels and associated systems configured to be mounted on the roof of a building for producing electrical energy when exposed to sunlight.

### BACKGROUND

Collecting energy directly from the sun has drawn more and more interest in the past several years as people and industries turn to more sustainable forms of energy production. One way to collect energy from the sun is through the use of photovoltaic panels that generate electrical energy when the panels are exposed to sunlight. Large numbers of such panels can be erected in an array and electrically interconnected to generate correspondingly large amounts of electrical energy. This energy is converted to electrical power when used to operate appliances, machinery, and the like. Such photovoltaic arrays have been used to supply electrical energy for commercial manufacturing plants, wineries, commercial buildings, and even domestic buildings. Such systems unfortunately tend to be large, bulky, unsightly, and generally not aesthetically desirable for installation on the roof of one's home.

More recently, photovoltaic systems have been developed that are designed to be installed on the roof of a residential home and, when installed, to present a more pleasing and acceptable appearance. One example is relatively flat, installed in a manner similar to normal asphalt shingles, and at least to some degree resembles ordinary shingles. These more recent systems, while a step in the right direction, have generally been less acceptable than expected for a number of reasons including their tendency to leak, their susceptibility to large reductions in efficiency when one or a few panels of the system are shaded, and the difficulty of detecting and replacing defective panels and/or defective electrical connections beneath the panels. These systems generally also require large inverters in a garage or other location that convert the direct current (DC) electrical energy generated by the panels to alternating current (AC) electrical energy for connection to the public grid.

Photovoltaic panels with micro-inverters mounted to their back surfaces have been proposed. In such systems, DC electrical energy produced by the photovoltaic panel is converted at the panel itself to AC electrical energy. However these panels tend to be thick and unsightly because of the spacing and cooling requirements of the micro-inverters (the panels are generally secured to a support frame that elevates the panels above the deck of the roof), in addition to the combined thickness of the photovoltaic panel atop the micro-inverters.

Consequently, a need persists for a roof integrated solar panel system that addresses the above and other problems and shortcomings, that is suitable in appearance and function for use on the roofs of residential homes, and that is easily installed and easily serviced. It is to the provision of such a system that the present invention is primarily directed.

### SUMMARY

Briefly described, a roof integrated solar panel system is disclosed for installation on the roof of a residential home to produce electrical energy when exposed to the sun. By “roof integrated” it is meant that the system also functions as the roofing membrane of the building to shed water and protect the roof deck. The system comprises a plurality of solar modules each including a frame, a solar or photovoltaic panel mounted to the frame, and an electrical coupling or junction box for connecting the module to other modules and/or to a micro-inverter. The system can further include a specially designed ridge vent designed to span the ridge of a roof and, if elected, to provide ventilation of the attic space below. The ridge vent is also designed to house and cover a plurality of micro-inverters spaced along the length of the ridge vent. In one embodiment, each micro-inverter is capable of converting DC electrical energy from the photovoltaic panels of two, three, or more solar modules to AC electrical energy.

During installation, solar modules of the system are secured against or flush to a roof deck below the ridge of the roof, so that the solar modules are resting on the roof deck. The modules may be installed in courses with the forward edges of higher courses overlapping a headlap region of modules in the next lower course to resemble a traditional shingle installation and to shed water during rain. The modules of each course may be staggered with respect to the modules in adjacent courses or they may be aligned with modules in adjacent courses. In one embodiment, the solar modules are generally electrically connected together in groups or “banks” of modules such as, for example, three solar modules per bank. DC electrical energy from each bank of solar modules is then delivered to one micro-inverter in the ridge vent, which converts the DC electrical energy produced by the bank into AC electrical energy. In this way, fewer micro-inverters are required. Furthermore, any degradation of one bank of solar modules due, for instance, to shading does not affect the electrical output of other banks of solar modules.

Accordingly, a roof integrated solar panel system is disclosed that addresses the problems and shortcomings mentioned above. The solar modules can be significantly thinner since they do not carry micro-inverters, fewer micro-inverters are required thereby reducing cost, and the system is robust in its resistance to efficiency reduction due to shaded solar panel banks. These and other objects, aspects, and advantages of the system will become more apparent upon review of the detailed description set forth below taken in conjunction with the accompanying drawing figures, which are briefly described as follows.

### BRIEF DESCRIPTION OF THE DRAWINGS

FIG. 1 is a perspective view of a portion of a roof illustrating a roof integrated solar panel system according to aspects of the invention.

FIG. 2 is a side elevation of the roof of FIG. 1 illustrating the overlapping solar modules and wiring according to the invention.

FIG. 3 is a cross sectional view along the shiplap joint between two end-to-end solar modules showing water management features.

FIG. 4 is an electrical schematic illustrating one possible electrical wiring scheme for connecting together components of the system.

### DETAILED DESCRIPTION

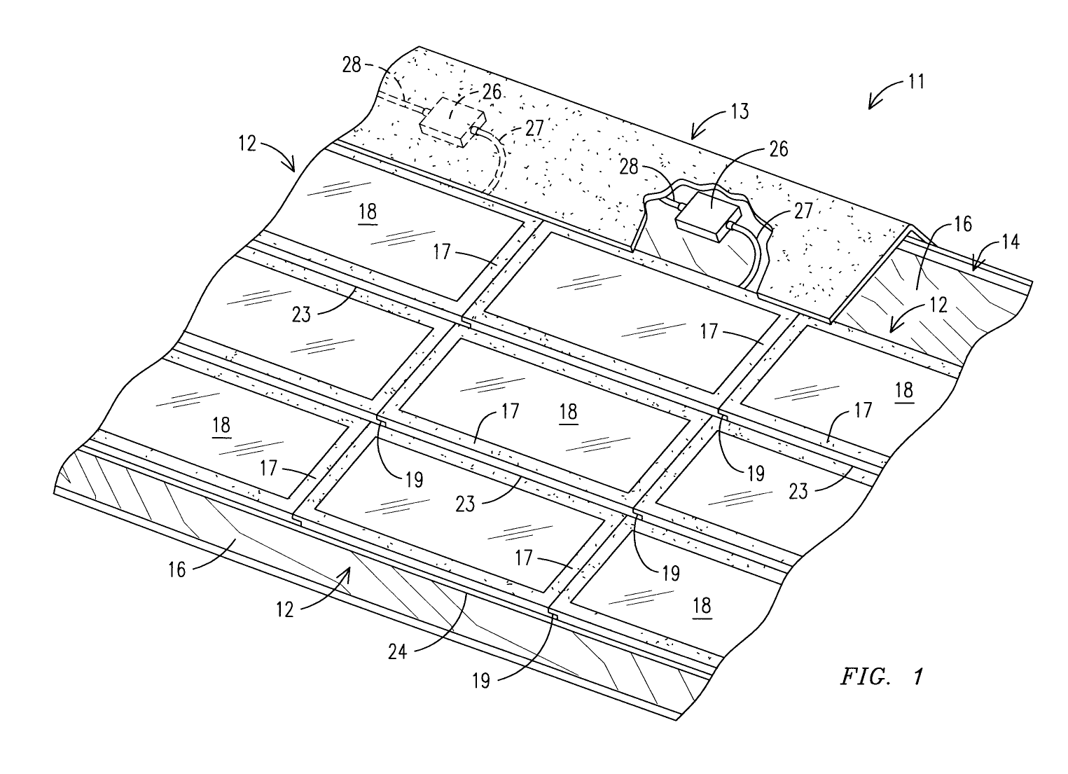

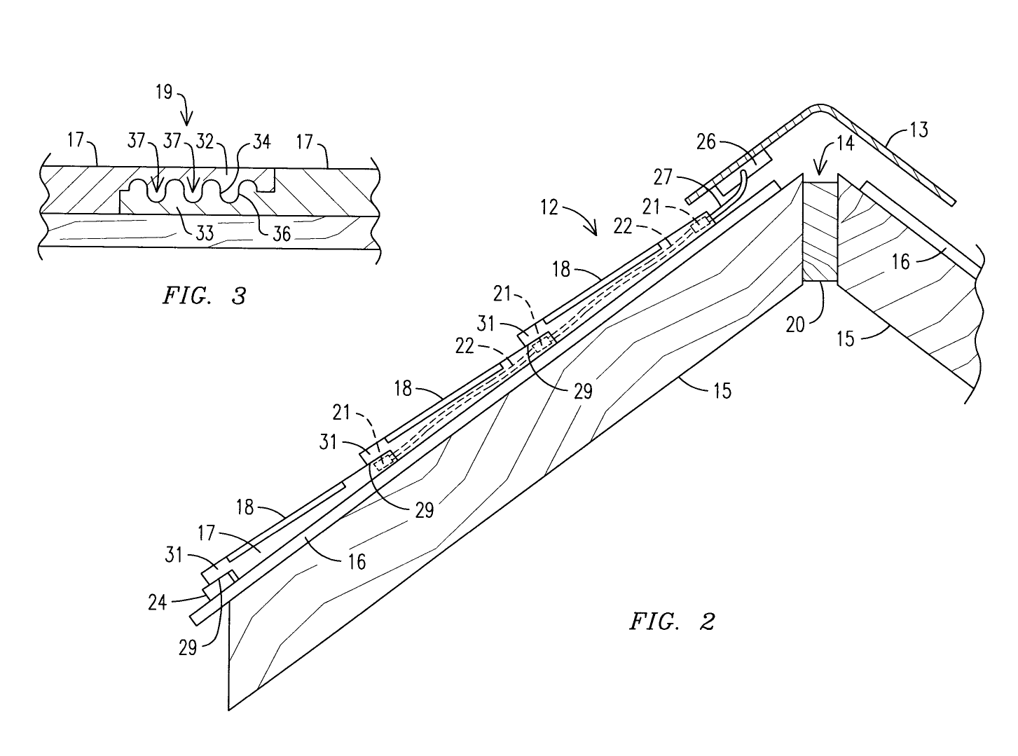

Referring now in more detail to the drawing figures, wherein like reference numerals, where appropriate, indicate like parts throughout the several views, FIG. 1 illustrates a section of a pitched roof commonly found in residential homes. The roof includes a roof deck 16 supported by rafters 15 (FIG. 2) and extending from a lower edge or eve upwardly to a ridge. In the illustrated embodiment, the ridge of the roof is formed with a ridge slot 14 for ventilation of an attic space below the roof. The roof deck 16 is illustrated as being plywood in FIG. 1, but may be other materials commonly used to deck roofs. Further, it will be understood by the skilled artisan that a membrane such as roofing felt or other material typically can be applied atop the roof deck and may overlie the roof deck even through it is not shown in the drawing figures.

A roof integrated solar panel system 11 is mounted on the roof in FIG. 1 and comprises a plurality of solar modules 12 secured in courses atop the roof deck. A special ridge vent 13 can extend along the ridge of the roof covering the ridge slot 14. Where the ridge vent is not used for ventilation of the attic space below the roof deck, there may be no ridge slot. The solar modules 12 in the illustrated embodiment are aligned with each other from course to course, but may be installed in staggered or installed in other patterns if desired.

Each solar module 12 generally includes a frame 17 and a photovoltaic panel 18. The frame 17 may be formed of molded or extruded plastic or other polymer material, formed of aluminum, formed of a composite material, or otherwise made of a material resistant to years of harsh environments encountered atop a typical roof. Each module has a forward edge, a rear edge, and left and right ends. In addition, the frame 17 of each solar module 12 can be slightly wedge shaped in cross section being thinner along the rear edge than the forward edge. In one aspect, the maximum thickness of the frames 17 can be less than or about one inch, or even less than or about one-half inch, so as to form a low-profile covering that extends across the surface of the roof deck 16 and has an appearance similar to that of more traditional roofing systems.

The forward edge of each frame 17 can be formed with an undercut groove 29 (FIG. 2) sized and configured to receive and overlap the rear edge portion of a solar module in a next lower course, which is referred to as the headlap 23. In this way, the modules of the system function to shed water during rain in a manner similar to traditional shingles. A starter strip 24 can be affixed along the forward edge portions of the lowermost course of modules and configured to nest within the undercut grooves 29 of these modules to support the modules and provide a weather barrier.

The frame 17 of each module carries a photovoltaic panel 18, which may be protected by a glass covering, a polymer coating, or other transparent material resistive to the elements. When exposed to sunlight, the photovoltaic panels 18 generate DC electrical energy. An electrical coupling, such as a junction box 21 or similar coupling device, is provided to allow the photovoltaic panel to be electrically connected to the photovoltaic panels of other solar modules or to another destination. In one aspect, the junction box 21 can be located in the rear or headlap portion 23 of each solar module 12 and below the top surface of the frame 17, and may thus be covered by the forward edge of an overlying solar module after installation.

A plurality of micro-inverters 26 are disposed beneath the ridge vent 13 where they are protected from the elements and also exposed to sufficient airflow to promote cooling of the micro-inverters during operation. Each micro-inverter converts DC electrical energy applied to its input to AC electrical energy at its output. In the illustrated embodiment, the DC electrical energy generated by two or more solar modules 18 can be applied through an electrical connector or wires 27 to the input of a corresponding micro-inverter 26. Since each micro-inverter is generally dedicated to more than one solar module, the number of micro-inverters required can be reduced, resulting in a reduction of system cost. However, even in embodiments where only one solar module 12 is electrically coupled to a single micro-inverter 26, advantages such as thinner modules, improved micro-inverter access and maintenance, and enhanced cooling, to name a few, are nevertheless realized.

In the illustrated embodiment, three solar modules 12 are electrically grouped into a “bank” of solar modules that is in turn connected to one micro-inverter at the ridge of the roof. It should be understood, however, that this is not a limitation of the invention and more or fewer solar modules, and even a single module, may be paired with each micro-inverter if desired. Although illustrated as being connected across several courses of solar modules, the electrically connected photovoltaic panels 18/solar modules 12 in the grouping need not be physically connected or adjacent to each other, and may be spaced from each other across the plurality of solar modules, if so desired.

In addition, the number of solar modules 12 that are grouped into banks and electrically coupled to a single micro-inverter 26 can be optimized according to the power output of the of photovoltaic panels 18 and the power capacity of the micro-inverters 26. Thus, the roof integrated solar panel system 11 of the present disclosure can also allow for “power matching” of the photovoltaic panels with the micro-inverters during the design stages of the solar panel system 11 for optimum efficiency and output.

Generally, the AC outputs of the micro-inverters 26 are then connected and aggregated together and delivered to a remote electrical system, such as the public electrical grid, a private electrical system in the building having appliances to be powered, or otherwise stored in batteries, used, or sold as desired.

FIG. 2 is a side elevation of the system shown in FIG. 1 illustrating three courses of solar modules 12. The frame 17 of each module can slightly wedge shaped with a forward edge formed with an undercut groove 29 and a relatively thinner rear edge. The solar modules 12 can be installed on the roof deck 16 in courses, with the undercut grooves 29 of higher courses receiving and overlying the thinner rear edges or headlap regions of modules in lower courses, so that water is shed down the modules during rain. Thus, when the solar modules 12 are secured or mounted flush to the roof with the bottom surfaces of the frames 17 resting on the deck 16 of the roof (or upon the roofing felt layer, etc.), the installed courses of solar modules 12 can together form a water-shedding barrier that protects the roof deck 16 from moisture.

In addition to a frame 17, each solar module 12 generally includes a photovoltaic panel 18 and an electrical coupling or junction box 21 from which output wires 22 extend. In the illustrated embodiment, three solar modules 12, one from each of the three separate courses of solar modules, are electrically coupled together through their junction boxes 21 and wires 22 in a group or bank. The bank of three solar modules is in turn electrically coupled to a single micro-inverter 26 that is housed and protected beneath a ridge vent 13 extending along the ridge of the roof. Starter strip 24 is seen disposed in the undercut groove 21 of the lowermost course of modules to fill the groove, support the modules, and form a weather barrier. Additional groupings of modules 12 (whether vertical, horizontal, or some other footprint) can be similarly connected along the roof, as shown in FIG. 1, and can provide DC electrical energy to additional micro-inverters beneath the ridge vent. As stated above, the AC outputs of the several micro-inverters can be coupled together to deliver aggregated AC electrical energy to the remote electrical system for use or storage.

It is to be appreciated that other configurations and devices for establishing electrical connections between solar modules 12 and between the solar modules 12 and the micro-inverters 26 are also possible and considered to fall with the scope of the present disclosure.

FIG. 3 illustrates one aspect of the end-to-end (i.e. side-to-side) connection between the frames 17 of two solar modules in the same course of modules. As shown, the overlap portion 32 of the left module can be formed along its bottom surface with a series of ridges and troughs 34 and the underlap portion 28 of the right module can be formed along its top surface with a series of complementing ridges and troughs 36. When two modules are joined end-to-end to form a shiplap, their respective ridges and troughs can interleave to form grooves 37 between the overlapped portions. This, in turn, can prevent water from migrating laterally across the shiplap joint and thereby inhibits water leakage between modules in a course of modules. However, any collected water within the grooves 37 can migrate along the grooves and be shed to the next lower course of modules and eventually off of the roof deck.

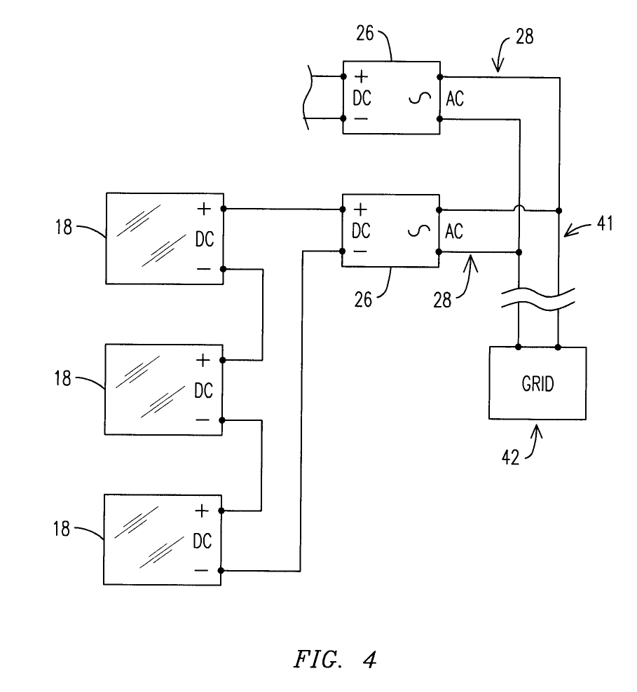

FIG. 4 illustrates one possible wiring schematic for electrically connecting banks of solar modules together and to their micro-inverter, and of connecting the micro-inverters of each bank together to deliver AC electrical energy to the grid. In the illustrated schematic, the photovoltaic panels 18 of three solar modules are shown electrically coupled together in a bank; however, more or fewer than three may comprise a bank such that any number of panels connected in a bank is within the scope of the invention. The three photovoltaic panels 18 in the illustrated embodiment can each produce a DC output when exposed to sunlight, and the DC outputs of each panel can be coupled in series with the DC outputs of the other photovoltaic panels in the bank. Thus connected, the voltages produced by the three panels are added together to produce a group DC voltage.

The group DC voltage of the connected bank of photovoltaic panels may be connected to the DC input of a micro-inverter 26, which converts the DC voltage to AC electrical energy at the output of the micro-inverter. Other micro-inverters of other banks of solar modules can also produce AC electrical energy from the DC electrical energy produced by their corresponding bank of solar modules. The AC outputs of all of the micro-inverters of an installation can be electrically coupled together in parallel to aggregate the AC outputs of all micro-inverters. The aggregated AC electrical energy can then be delivered via a common electrical line 41 to a remote electrical system, such as the public electrical grid 42, a private home electrical system, and the like, for use or storage.

FIG. 4 illustrates one possible electrical schematic for interconnecting modules of the system. It will be understood, however, that many other ways of wiring and interconnecting the modules and micro-inverters are possible depending upon a desired output and result and all are considered to be within the scope of the invention. For instance, the DC outputs of the three modules may be electrically connected in parallel instead of in series as shown and/or the AC outputs of the micro-inverters may be electrically connected in series rather than in parallel. All useful electrical connection schemes should be considered to be within the scope of the invention.

The invention has been described herein in terms of preferred embodiments and methodologies considered by the inventor to represent the best mode of carrying out the invention. It will be understood by the skilled artisan; however, that a wide range of additions, deletions, and modifications, both subtle and gross, may be made to the illustrated and exemplary embodiments without departing from the spirit and scope of the invention set forth in the claims.

What is claimed is:

1. A roof integrated solar panel system for generating electrical power from sunlight, the solar panel system comprising:
a plurality of solar modules secured to a deck of a roof, each solar module having a frame, a photovoltaic panel mounted to a portion of the frame, and at least one electrical coupling allowing an electrical output of the photovoltaic panel to be connected to a remote location on the roof; and
a plurality of micro-inverters secured to the roof at the remote location, the plurality of solar modules being electrically coupled in banks of solar modules to corresponding micro-inverters, each micro-inverter transforming the DC electrical energy from a bank of solar modules to AC electrical energy,
wherein the AC electrical energy from the plurality of micro-inverters is aggregated together and delivered to a remote electrical system.

2. The solar panel system of claim 1, wherein the bank of modules further comprises two or more photovoltaic panels electrically connected in series.

3. The solar panel system of claim 1, wherein the plurality of micro-inverters are electrically connected together in parallel.

4. The solar panel system of claim 1, wherein the plurality of solar modules are secured to the deck of the roof in courses and a first bank of modules further includes electrically connected photovoltaic panels from two or more courses.

5. The solar panel system of claim 1, wherein the remote location is proximate a ridge of the roof.

6. The solar panel system of claim 5, wherein the remote location is beneath a ridge vent extending along the ridge of the roof.

7. The solar panel system of claim 1, wherein the plurality of solar modules form a water-shedding barrier protecting the roof.

8. The solar panel system of claim 7, wherein a bottom surface of the frame of the solar module rests upon the deck of the roof.

9. The solar panel system of claim 7, wherein the frames of the solar modules further comprise edge features configured to couple with corresponding edge features of adjacent frames to form the water-shedding barrier.

10. The solar panel system of claim 9, wherein edge features on the ends of the frames include complementary ridges and troughs that form shiplap joints with the frames of laterally-adjacent solar modules.

11. The solar panel system of claim 9, wherein edge features on the forward edges of the frames include undercut grooves that overlap the rear edges of the frames of an adjacent lower course of solar modules.

12. The solar panel system of claim 1, wherein a maximum thickness of the frame of the solar module is less than or about one inch.

13. The solar panel system of claim 12, wherein a maximum thickness of the frame of the solar module is less than or about one half inch.

14. The solar panel system of claim 1, wherein the at least one electrical coupling includes a junction box positioned below a top surface of the frame.

15. A roof integrated solar panel system for generating electrical power from sunlight on a roof having a ridge, the solar panel system comprising:
a plurality of solar modules mounted on the roof to form at least one bank of solar modules, each solar module producing DC electrical energy when exposed to sunlight;
a ridge vent extending at least partially along the ridge of the roof;
at least one micro-inverter secured to the roof proximate the ridge and beneath the ridge vent; and
at least one electrical connector connecting a bank of solar modules to a micro-inverter for converting DC electrical energy from the bank of solar modules to AC electrical energy.

16. The solar panel system of claim 15, wherein the bank of solar modules further comprises two or more solar modules electrically connected in series.

17. The solar panel system of claim 16, wherein the plurality of solar modules are secured to the deck of the roof in courses and the bank of modules includes electrically connected solar modules from two or more courses.

18. The solar panel system of claim 15, wherein at least one micro-inverter further comprises a plurality micro-inverters electrically connected in parallel.

19. The solar panel system of claim 15, wherein the plurality of solar modules form a water-shedding barrier protecting the roof.

20. A method of generating electrical power from sunlight on a roof having a ridge and a ridge vent extending at least partially along the ridge of the roof, the method comprising:
mounting a plurality of micro-inverters to the roof proximate the ridge and beneath the ridge vent;
mounting a plurality of solar modules to the deck of the roof, each module comprising a frame, a photovoltaic panel mounted to a portion of the frame, and an electrical coupling for outputting DC electrical energy from the photovoltaic panel;
electrically connecting the electrical couplings of the solar modules into banks of solar modules;
electrically connecting each bank of solar modules to one of the plurality of micro-inverters to transform the DC electrical energy from the banks of solar modules to AC electrical energy; and
electrically connecting the plurality of micro-inverters to a remote electrical system to aggregate and deliver the AC electrical energy to the remote electrical system.
